(19) United States
(12) Patent Application Publication
(10) Pub. No.: US 2014/0117972 A1
(43) Pub. Date: May 1, 2014

(54) CURRENT DETECTION CIRCUIT

(71) Applicant: Sanken Electric Co., Ltd., Niiza-shi (JP)

(72) Inventors: Akiteru CHIBA, Niiza-shi (JP); Keita ISHIKURA, Niiza-shi (JP)

(73) Assignee: Sanken Electric Co., Ltd., Niiza-shi (JP)

(21) Appl. No.: 14/035,106

(22) Filed: Sep. 24, 2013

(30) Foreign Application Priority Data
Oct. 29, 2012 (JP) 2012-237828

(51) Int. Cl. G01R 19/00

(52) U.S. Cl. CPC G01R 19/0092
USPC 324/76.11

(57) ABSTRACT

Provided is a current detection circuit which can reduce the resistance loss for a current transformer, meeting the requirements for size and cost thereof. The current detection circuit includes a current transformer and a capacitor connected across a secondary winding of the current transformer, the capacitor making a phase adjustment such that the primary side current flowing through the primary winding of the current transformer and the voltage across the capacitor are in phase with each other. With this configuration, the primary side current can be detected as the voltage across the capacitor with no need for using a matching resistor, with which, if the winding ratio of the current transformer is small, the resistance loss will be large, whereby a current detection circuit of low loss using a current transformer which is small in size and low in cost can be configured.

### BACKGROUND OF THE INVENTION

1. Field of the Invention

The present invention relates to a current detection circuit using a current transformer.

2. Description of the Related Art

As shown in FIG. 5, the conventional current detection circuit using a current transformer includes a current transformer CT, a primary winding Np thereof being installed in a line where to detect the current, and a resistor R2 installed across a secondary winding Ns of the current transformer CT. The resistor R2 installed across the secondary winding Ns is called a matching resistor, and across the terminals of the resistor R2, there is outputted a voltage Vs corresponding to a primary side current ip flowing through the line in which the primary winding Np is installed (for example, refer to Patent Document 1).

Patent Document 1: Japanese Unexamined Patent Application Publication No. 2007-299838

However, with the prior art, there has been a problem that it is difficult to meet all the requirements for the degree of resistance loss W of the resistor R2 as a matching resistor, and the size and cost of the current transformer CT.

Assuming that the current value of the primary side current ip is ip; the current value of the secondary side current ‘is’ is ‘is’; the number of turns of the primary winding Np is Np; the number of turns of the secondary winding Ns is Ns; the turns ratio between the primary winding Np and the secondary winding Ns is N (=Ns/Np); the secondary side output voltage outputted across the terminals of the resistor R2 is Vs; and the resistance value of the resistor R2 is R,

on the law of equal ampere-turns,

‘is’=(Np/Ns)·ip=ip/N,

Therefore, the secondary side output voltage Vs which is generated on the secondary side is Vs=R·ip/N.

In addition, the resistance loss W caused by the resistor R2 as a matching resistor is W=R·is₂=R(ip/N)₂.

Therefore, in the case where a current of 1 A is caused to flow on the primary side to generate a voltage of 1 V on the secondary side, the relation between the turns ratio N (=Ns/Np) and the resistance loss W is as expressed in FIG. 6. As can be seen from FIG. 6, in order to lower the resistance loss W, the turns ratio N must be increased. Increasing the turns ratio N would provide a larger-sized current transformer CT, which leads to an increase in cost. Contrarily, lowering the turns ratio N in order to make the current transformer CT smaller in size would increase the resistance loss W. Thus, between the resistance loss W and the turns ratio N of the current transformer CT, there is a contradictory relationship, and therefore it is difficult to satisfy the requirements for both at the same time. By the way, the ordinal current transformer CT is used with the primary winding Np where the current is caused to flow being provided with one turn, thereby the winding ratio N is determined by Ns, i.e., the number of turns on the secondary side.

The present invention has been made in view of the above problem of the prior art, and it is an object of the present invention to solve such problem by providing a current detection circuit which can reduce the resistance loss W, and satisfy the requirements for both size and cost of the current transformer CT at the same time.

### SUMMARY OF THE INVENTION

A current detection circuit of the present invention includes a current transformer, and a capacitor connected across a secondary winding of the current transformer, the voltage across the capacitor being phase-adjusted to be in phase with the primary side current flowing through the primary winding of the current transformer.

Further, the current detection circuit of the present invention may be adapted to include a series circuit of a resistor connected across the secondary winding of the current transformer and the capacitor, the series circuit phase-adjusting the voltage across the capacitor to be in phase with the current flowing through the primary winding of the current transformer.

Further, the current detection circuit of the present invention may be adapted such that, assuming that the resistance value of the resistor is R; the capacitance of the capacitor is C; the secondary side inductance of the current transformer is Ls; the secondary side leakage inductance of the current transformer is Lr; and the secondary winding resistor of the current transformer is Rr, the resistor and the capacitor are set to satisfy a relation of RC=(Ls+Lr)/R.

In accordance with the present invention, there is provided an advantage that the primary side current ip can be detected with no need for using a matching resistor with which, if the winding ratio of the current transformer CT is small, the resistance loss is large, whereby a current detection circuit of low loss using a current transformer CT which is small in size and low in cost can be configured.

### BRIEF DESCRIPTION OF THE DRAWINGS

FIG. 1 is a circuit configuration diagram showing the circuit configuration of an embodiment of a current detection circuit in accordance with the present invention;

FIG. 2 is a graph showing a capacitor voltage waveform in the current detection circuit shown in FIG. 1;

FIG. 3 is a comparison diagram illustrating the relation between the turns ratio and the resistance value and that between the turns ratio and the resistance loss for the current detection circuit shown in FIG. 1 in comparison with those in the conventional current detection circuit;

FIG. 4 is a graph illustrating the operating range for the current detection circuit shown in FIG. 1;

FIG. 5 is a circuit configuration diagram showing the circuit configuration of the conventional current detection circuit; and

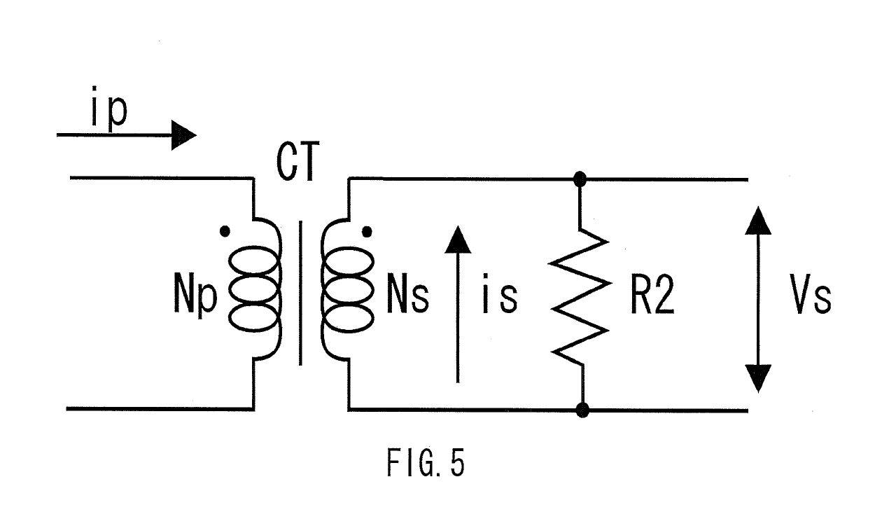

FIG. 6 is a graph illustrating the relation between the turns ratio of the current transformer and the resistance loss in the conventional current detection circuit.

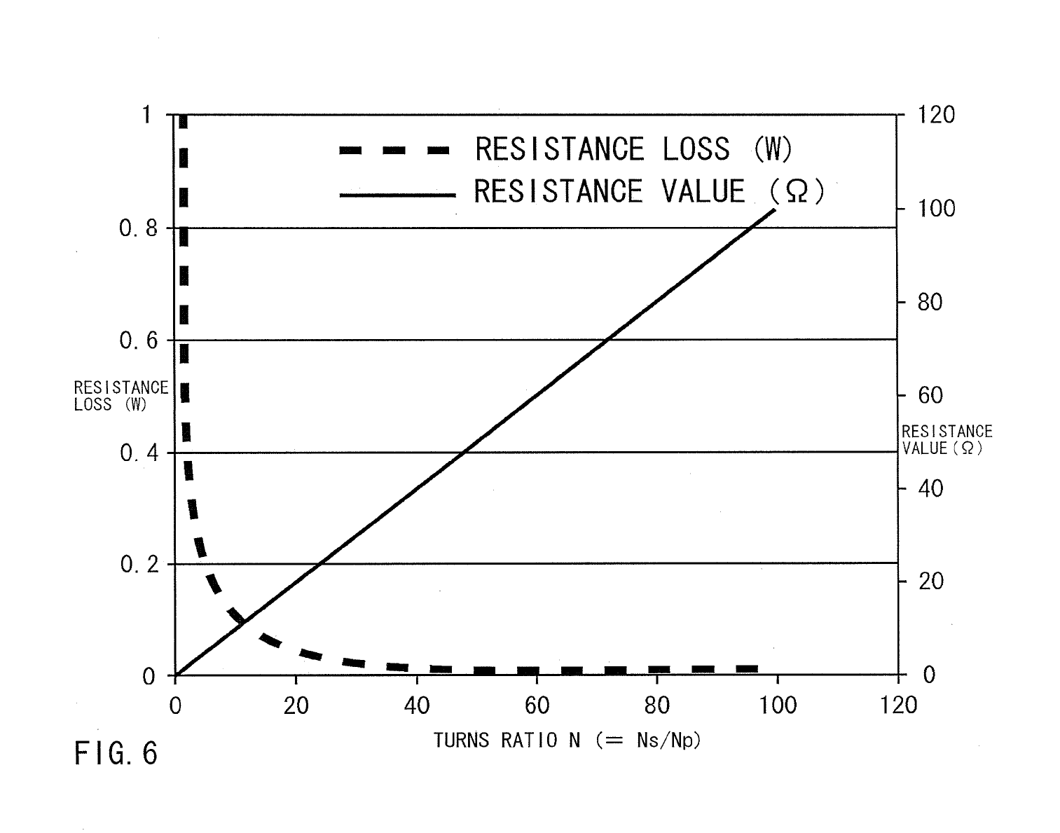

### DETAILED DESCRIPTION OF THE PREFERRED EMBODIMENT

Next, an embodiment of the present invention will be specifically explained with reference to the drawings.

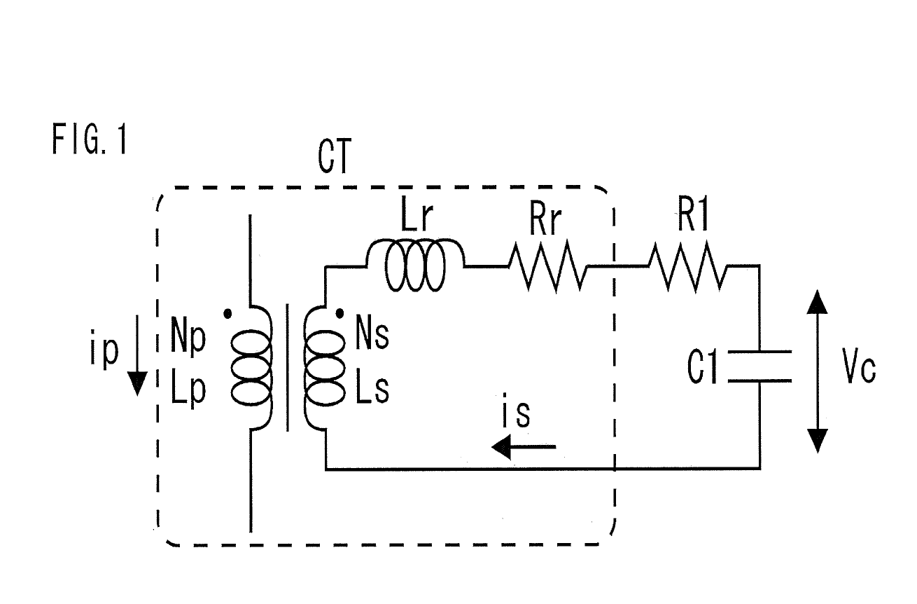

As shown in FIG. 1, the current detection circuit of the present embodiment includes a current transformer CT, a primary winding Np thereof being installed in a line where to detect the current, and a series circuit of a resistor R1 and a capacitor C1 connected across a secondary winding Ns of the current transformer CT.

The series circuit of the resistor R1 and the capacitor C1 is a circuit for making phase adjustment of the secondary side voltage of the current transformer CT. Assuming that the resistance value of the resistor R1 is R, and the capacitance of the capacitor C1 is C, the R·C is set to satisfy a relation of the following expression “Math 1”.

$$R \cdot C = \frac{Ls + Lr}{Rr} \qquad [ Math 1 ]$$

In FIG. 1 and “Math 1”, reference symbol Ls denotes the secondary side inductance of the current transformer CT; Lr the secondary side leakage inductance of the current transformer CT; and Rr the secondary winding resistor of the current transformer CT. Further, in FIG. 1, reference symbol Lp denotes the primary side excitation inductance.

In the current detection circuit of the present embodiment, the phase adjustment made by the series circuit of the resistor R1 and the capacitor C1 which are set to satisfy the relation of the aforementioned “Math 1” reproduces the primary side current ip as the voltage Vc across the capacitor C1. In other words, the primary side current ip advances the phase of the voltage caused by the primary side excitation inductance Lp. Naturally, the secondary side voltage of the current transformer CT is provided with an advanced phase with respect to the primary side current ip, however, by connecting the series circuit of the resistor R1 and the capacitor C1, the phase is delayed to be returned to the same phase as that of the original primary side current ip.

Assuming that the current flowing on the secondary side is is(t), and the voltage across the capacitor is vc(t), the voltage drop across the closed network on the secondary side can be expressed by the following expression “Math 2”.

$$vc ( t ) + RC \frac{d vc ( t )}{d t} + Rr * is ( t ) + ( Ls + Lr ) \frac{d is ( t )}{d t} = 0 \\ Taking the Laplace transform , we have \text{:} [ vc ( t ) ] = Vc \\ [ is ( t ) ] = Is ( t ) \\ Vc ( 1 + sRC ) = - IsRr \{ 1 + s \frac{Ls + Lr}{Rr} \} \qquad [ Math 2 ]$$

Further, the relation in current between the primary side and the secondary side can be expressed by the following expression “Math 3” with the winding polarity being taken into account. In “Math 3”, reference symbol N denotes the turns ratio (Ns/Np) for the current transformer CT.

$$Vc = - IsRr \frac{1 + s \frac{Ls + Lr}{Rr}}{1 + sRC} = \frac{IpRr}{N} \cdot \frac{1 + s \frac{Ls + Lr}{Rr}}{1 + sRC} \qquad [ Math 3 ]$$

Therefore, by setting the resistor R1 and the capacitor C1 to satisfy the relation of the aforementioned “Math 1”, the is(t) and the vc(t) are expressed by the following expression “Math 4”, and it can be known that the primary side current ip is reproduced by means of the voltage Vc across the capacitor C1.

$$Vc = \frac{1}{N} \cdot Rr \cdot Is \\ Taking the inverse Laplace transform , we have \text{:} \\ ∴ vc ( t ) = \frac{1}{N} \cdot Rr \cdot is ( t ) \qquad [ Math 4 ]$$

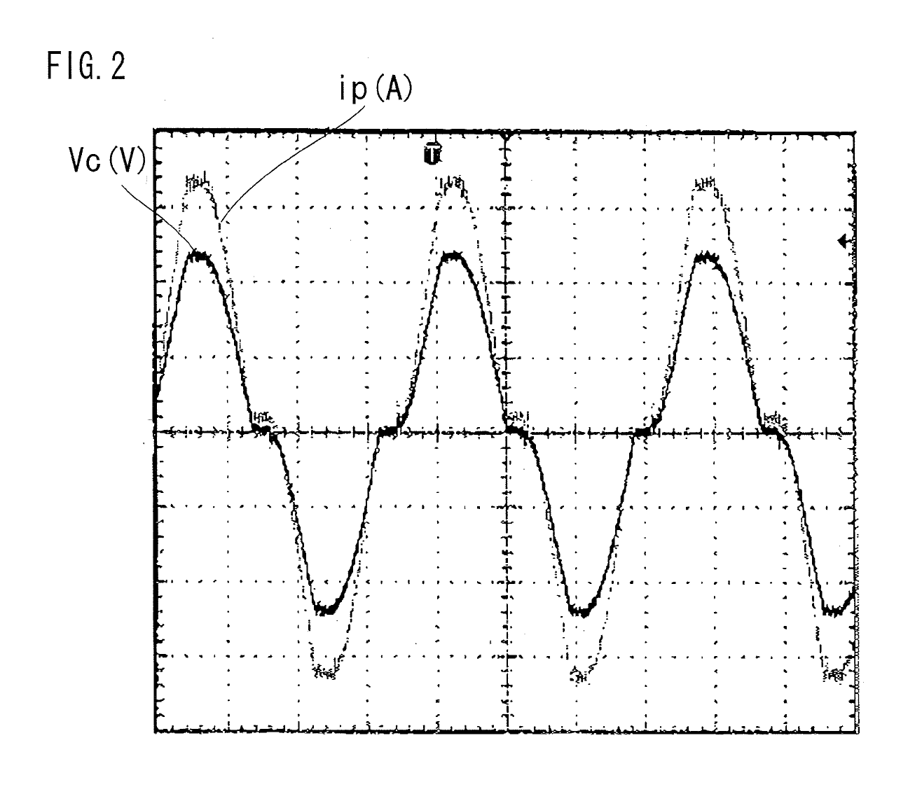

In FIG. 2, there is shown a voltage waveform of the voltage Vc across the capacitor C1 when, as the primary side current ip, an alternating current is caused to flow in the current detection circuit in the present embodiment. As shown in FIG. 2, the primary side current ip is reproduced by means of the voltage Vc across the capacitor C1.

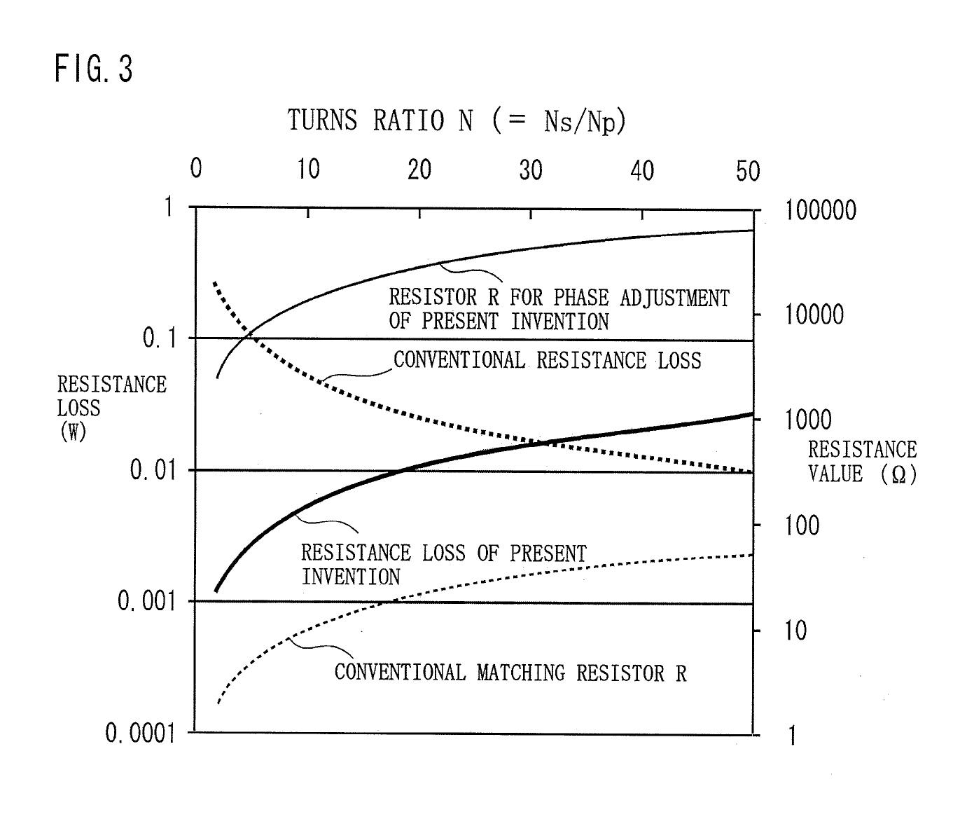

In FIG. 3, there are illustrated a relation between the turns ratio N (=Ns/Np) for the current transformer CT and the resistance value (that of the conventional matching resistor or the resistor for phase adjustment in the present embodiment), and a relation between the turns ratio N (=Ns/Np) for the current transformer CT and the resistance loss, for the conventional system using a matching resistor and the current detection circuit in the present embodiment, respectively.

The resistance loss gives a value in the case where a current of 1 A is caused to flow on the primary side to generate 1 V on the secondary side.

The data used for the calculation are as follows:

The current transformer CT used is of EI-12.5 core;

the primary side current ip for the current transformer CT is a current of a sine wave having a frequency f=150 kHz; and

the capacitance of the capacitor C1 for phase adjustment was fixed at 1000 pF for calculation.

Further, the loss W for the phase adjustment resistor R1 is calculated on the basis of the voltage Vc across the capacitor C1 and the secondary side current ‘is’ which are given in the following expression “Math 5”.

$$ω = 2 π f \\ Vc = \vert \frac{( 1 - {ω}^{2} LrC ) - j ω ( R + Rr ) C}{{( 1 - {ω}^{2} LrC )}^{2} + {\{ ω ( R + Rr ) C \}}^{2}} \vert Lp \frac{1}{N} ip \cdot sin \{ ω t + arctan ( - \frac{ω ( R + Rr ) C}{1 - {ω}^{2} LrC} ) \} \\ is = C \frac{d vc}{d t} \\ W = R \cdot {is}^{2} \qquad [ Math 5 ]$$

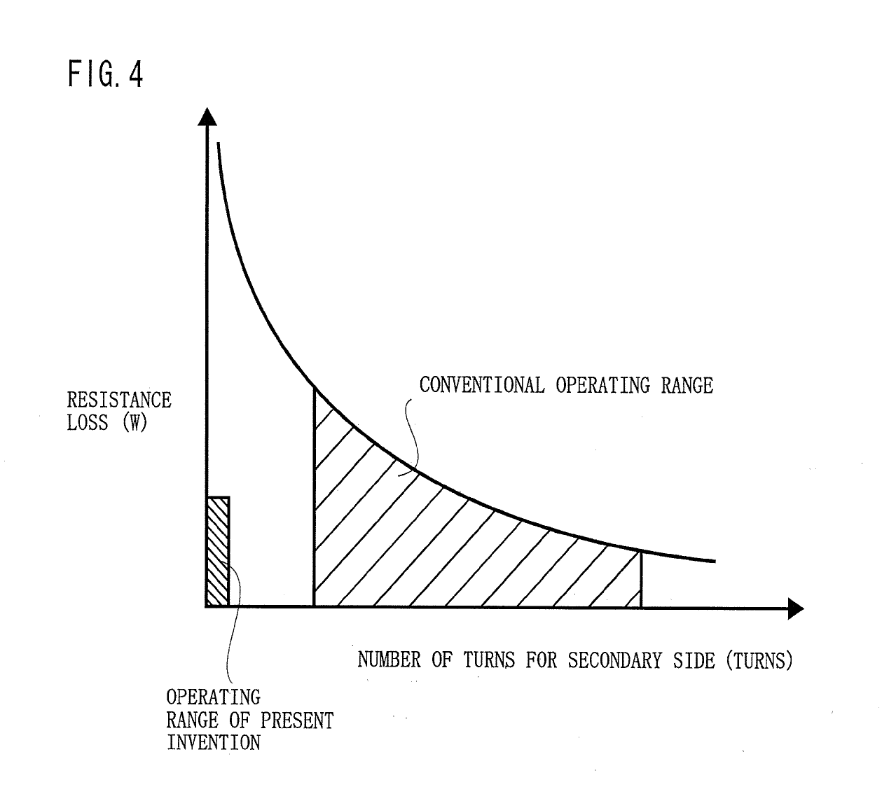

FIG. 3 illustrates that, in the current detection circuit in the present embodiment, the smaller the value of turns ratio N for the current transformer CT, the more the resistance loss is reduced. FIG. 4 illustrates the difference in operating range between the conventional system and the current detection circuit of the present invention. FIG. 4 shows that the region where the secondary side number of turns Ns is small provides the operating range for the current detection circuit of the present invention. In this way, in accordance with the present invention, a current detection circuit using a current transformer CT which is small in size and low in loss, and allows current-voltage conversion to be accurately performed can be configured.

The present embodiment is configured such that the series circuit of the resistor R1 and the capacitor C1 performs phase adjustment, however, the resistor R1 is not always required, and the present embodiment may be configured such that the capacitor C1 and the secondary winding resistor Rr for the current transformer CT are used to make phase adjustment.

As described above, according to the present embodiment, there are provided the current transformer CT and the capacitor C1 which is connected across the secondary winding Ns of the current transformer CT, and with the capacitor C1, the voltage Vc across the capacitor C1 is phase-adjusted to be in phase with the primary side current ip flowing through the primary winding Np of the current transformer CT. With this configuration, the primary side current ip can be detected as the voltage Vc across the capacitor C1 with no need for using a matching resistor, with which, if the winding ratio of the current transformer CT is small, the resistance loss will be large, whereby a current detection circuit of low loss using a current transformer CT which is small in size and low in cost can be configured.

Further, according to the present embodiment, there is provided the series circuit of the resistor R1 which is connected across the secondary winding Ns of the current transformer CT and the capacitor C1, and with this series circuit, the voltage Vc across the capacitor C1 is phase-adjusted to be in phase with the primary side current ip flowing through the primary winding Np of the current transformer CT. With this configuration, a capacitor C1 having a low capacitance can be used, whereby the cost can be reduced.

Further, according to the present embodiment, assuming that the resistance value of the resistor R1 is R; the capacitance of the capacitor C1 is C; the secondary side inductance of the current transformer CT is Ls; the secondary side leakage inductance of the current transformer CT is Lr; and the secondary winding resistor of the current transformer CT is Rr, the resistor R1 and the capacitor C1 are set to satisfy a relation of RC=(Ls+Lr)/R. With this configuration, the resistor R1 and the capacitor C1 which constitute the series circuit for phase adjustment can be simply selected according to the characteristics of the current transformer CT.

Hereinabove, the present invention has been explained with a specific embodiment, however, the above embodiment is an example, and needless to say, it may be modified within the scope of the spirit of the present invention for implementation.

What is claimed is:

1. A current detection circuit, comprising: a current transformer, and
a capacitor connected across a secondary winding of the current transformer,
the voltage across said capacitor being phase-adjusted to be in phase with the primary side current flowing through the primary winding of said current transformer.

2. The current detection circuit according to claim 1, wherein there is provided a series circuit of a resistor connected across the secondary winding of said current transformer and said capacitor,
said series circuit phase-adjusting the voltage across said capacitor to be in phase with the current flowing through the primary winding of said current transformer.

3. The current detection circuit according to claim 2, wherein, assuming that the resistance value of said resistor is R; the capacitance of said capacitor is C; the secondary side inductance of said current transformer is Ls; the secondary side leakage inductance of said current transformer is Lr; and the secondary winding resistor of said current transformer is Rr, said resistor and said capacitor are set to satisfy a relation of RC=(Ls+Lr)/R.
